(19) United States
(12) Patent Application Publication
(10) Pub. No.: US 2007/0221953 A1
(43) Pub. Date: Sep. 27, 2007

(54) SEMICONDUCTOR DEVICE

(76) Inventor: Kozo Sakamoto, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/689,659

(22) Filed: Mar. 22, 2007

(30) Foreign Application Priority Data
Mar. 24, 2006 (JP) 2006-081905

(51) Int. Cl. H01L 29/74

(52) U.S. Cl. 257/155

(57) ABSTRACT

A semiconductor device such as a reverse blocking type switching element is provided with a switching element made of a wide band gap semiconductor on the side of a first major plane where a first terminal is formed, while the wide band gap semiconductor is operable at a high voltage and in low loss. In a reverse blocking type switching element having a hetero junction diode for blocking a reverse direction current on the side of a second major plane where a second terminal is formed, a silicon semiconductor region is provided in a side surface of the semiconductor so as to prevent a deterioration of a withstanding voltage of the hetero junction diode.

### BACKGROUND OF THE INVENTION

1. Field of the Invention

The present invention is related to a reverse blocking type semiconductor switching element operable in low loss and having a high withstanding voltage.

2. Description of the Related Art

Wide band gap semiconductor elements such as SiC (silicon carbide), GaN (gallium nitride), and diamond, whose band gaps are higher than, or equal to 1.3 eV, have the following features: That is, while these wide band gap semiconductor devices can be operated in a high voltage, low loss and at a high frequency, these semiconductor device can be further operated in a high temperature. As such a semiconductor device that a wide band gap semiconductor is contacted to a silicon semiconductor, JP-A-2002-16262 (will be referred to as “patent publication 1” hereinafter) discloses a vertical type field-effect transistor which is realized by forming a GaN-series material on an Si substrate (see FIG. 1 and paragraph [0011]).

On the other hand, there are reverse blocking IGBTs (Insulated Gate Bipolar Transistors) capable of improving reverse-direction blocking voltages of IGBTs with respect to application circuits such as matrix converters. JP-A-2006-294716 (will be referred to as “patent publication 2” hereinafter) discloses a reverse blocking IGBT which employs a silicon semiconductor having such a groove that a {111} plane is used as a side wall and a {100} plane is used as a bottom plane (see FIG. 1 and paragraph [0018]).

Furthermore, JP-A-2006-186307 (will be referred to as “patent publication 3” hereinafter) discloses a reverse blocking type switching element having a hetero junction diode in which a wide band gap semiconductor is contacted to a silicon semiconductor (see FIG. 1 and paragraph [0011]).

Among the above-described conventional technical ideas, although the patent publication 1 discloses such a structure that the wide band gap semiconductor is contacted to the silicon semiconductor, this patent publication 1 has not sufficiently considered the following points: That is, this contact plane is operated as a diode, and this junction is not operable under high withstanding voltage.

The patent publication 2 describes such a method that after the groove is formed in the reverse blocking-purpose isolating region of the silicon semiconductor substrate, this groove is embedded by the polycrystal silicon layer, or the epitaxial silicon layer. However, this patent publication 2 has not considered the manufacturing method and the semiconductor device structure, which are suitable for the wide band gap semiconductors.

The patent publication 3 has such a merit that since the depth direction of the semiconductor substrate is short, the manufacturing process of the peripheral structure can be simplified. However, this patent publication 3 has the following problem. That is, since the impurity diffusion speed in the wide band gap semiconductor is slow, if the isolation region is formed along the depth direction of the semiconductor substrate in such a manner that this isolation region is reached to the hetero junction diode from the first major plane (front surface) to the second major plane (rear surface), then the energy of the ion implantation may become excessively high, and/or the impurity diffusion time may become excessively long.

### SUMMARY OF THE INVENTION

An object of the present invention is to provide a high withstanding voltage semiconductor device provided with a reverse blocking function having a hetero junction and a switching function. More specifically, the present invention has another object to provide such a semiconductor device with employment of a high withstanding voltage wide band gap semiconductor operable in low loss.

To achieve the above-described objects, the semiconductor device, according to an aspect of the present invention, is featured by that in a reverse blocking type switching element having a hetero junction, another hetero junction is also formed on a side surface of a peripheral portion of a switching element in order to realize a high withstanding voltage of the hetero junction.

In accordance with the present invention, a wide bandgap semiconductor switching element operable under the high withstanding voltage and in low loss can be realized, while the wide band gap semiconductor switching element has the reverse blocking characteristic.

Other objects, features and advantages of the invention will become apparent from the following description of the embodiments of the invention taken in conjunction with the accompanying drawings.

### BRIEF DESCRIPTION OF THE DRAWINGS

FIG. 1 is a sectional view for showing a semiconductor device according to an embodiment 1 of the present invention.

FIG. 2 is a sectional view for representing a manufacturing step of the semiconductor device according to the embodiment 1.

FIG. 3 is a sectional view for showing a semiconductor device according to an embodiment 2 of the present invention.

FIG. 4 is a sectional view for representing a manufacturing step of the semiconductor device according to the embodiment 2.

FIG. 5 is a sectional view for indicating a semiconductor device according to an embodiment 3 of the present invention.

FIG. 6 is a sectional view for showing a semiconductor device according to an embodiment 4 of the present invention.

FIG. 7 is a sectional view for indicating a semiconductor device according to an embodiment 5 of the present invention.

FIG. 8 is a sectional view for showing a semiconductor device according to an embodiment 6 of the present invention.

FIG. 9 is a sectional view for indicating a semiconductor device according to an embodiment 7 of the present invention.

FIG. 10 is a sectional view for showing a semiconductor device according to an embodiment 8 of the present invention.

FIG. 11 is a sectional view for indicating a semiconductor device according to an embodiment 9 of the present invention.

FIG. 12 is a circuit diagram of a semiconductor device according to an embodiment 10 of the present invention.

FIG. 13 is a circuit diagram of a semiconductor device according to an embodiment 11 of the present invention.

### DESCRIPTION OF THE EMBODIMENTS

In a semiconductor circuit of the present invention, in a semiconductor switching element having a first junction and a second junction, at least one region within a major current path between a first main terminal and a second main terminal of the above-described semiconductor switching element is a wide band gap semiconductor; a forward direction voltage drop of the second junction is lower than a forward direction voltage drop of the first junction; when the switching element is turned ON in a forward direction operation, the second junction is brought into a forward bias condition; when the switching element is in a reverse bias status, the semiconductor switching element is brought into a current blocking status; and a unit is provided that when the semiconductor switching element is under the current blocking, status, a depletion layer of a peripheral edge portion of the second junction is elongated to the side of a first major plane where the first junction is formed.

### Embodiment 1

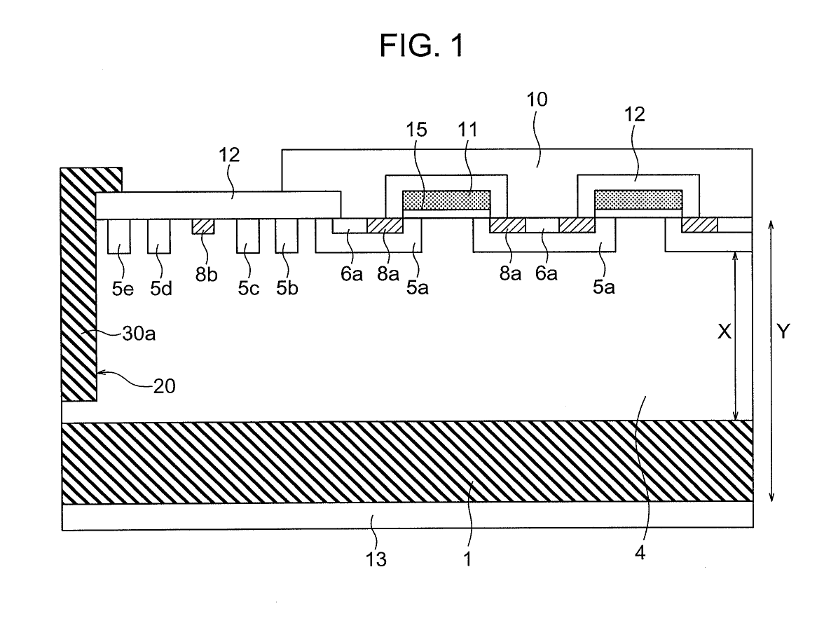

FIG. 1 is a semiconductor device of an embodiment 1 of the present invention. The semiconductor device of this embodiment 1 corresponds to a reverse blocking type SiC power MOSFET in which an SiC power MOSFET has been formed on the side of a first major plane, and a hetero junction diode has been formed between a polycrystal silicon semiconductor region 1 on the side of a second major plane and an n type SiC semiconductor region 4. In other words, an electrode layer 10 is a source electrode of the SiC power MOSFET, and the n type SiC semiconductor region 4 constitutes a drain region. However, the n type SiC semiconductor region 4 also constitutes a cathode region of the hetero junction diode, and the silicon semiconductor region 1 functions as an anode region of the hetero junction diode. As a consequence, an electrode layer 13 will be referred to as an anode electrode of the semiconductor device of this embodiment 1.

On the side of the first major plane, a p type body region 5a, floating field rings 5b and 5c which are formed in order to secure a drain withstanding voltage, an n type source region 8a, a contact-purpose p type semiconductor region 6a, a leak current reducing-purpose n type region 8b, a gate insulating film 15, a gate electrode layer 11, an insulating layer 12, and a source electrode layer 10 have been formed in an n type SiC semiconductor layer. Also, a polycrystal silicon semiconductor region 30a has been formed in the peripheral portion of the power MOSFET along a direction substantially perpendicular to the first major plane, and thus, a hetero junction diode has been formed between the polycrystal silicon semiconductor region 30a and the n type SiC semiconductor layer 4. Otherwise, more strictly speaking, the silicon semiconductor region 30a has been formed in such a manner that this silicon semiconductor region 30a surrounds a side surface of the high withstanding voltage securing region 4 of this semiconductor element. It should be understood that although both the n type regions 8a and 8b, and the p type regions 5a and 6a may be formed by performing ion implantation with high energy, these regions may be fabricated by utilizing an epitaxial step. In particular, as to a channel forming region just under the gate insulating film 15, an epitaxial layer may be additionally provided so as to optimize the threshold voltage.

In the semiconductor device of the present embodiment 1, a withstanding voltage under OFF state in the forward direction operation of the power MOSFET is secured by a first junction which is formed by the p type SiC semiconductor layer 5a and the n type SiC semiconductor layer 4, whereas a revere blocking withstanding voltage is secured by a hetero junction corresponds to a second junction which is formed by the polycrystal silicon semiconductor region 1 and the n type SiC semiconductor region 4. Also, similar to a Schottky diode, when this hetero junction diode is biased in the forward direction, a current mainly flows due to majority carriers, and substantially no minority carriers are implanted. As a consequence, the semiconductor device of this embodiment 1 constitutes a reverse blocking type SiC power MOSFET capable of performing a high-speed switching operation. It should also be understood that although this embodiment 1 exemplifies that the switching element is the power MOSFET, other switching elements such as JFET, MESFET, and bipolar transistors may be alternatively built. Also, as the switching element portion, instead of SiC, if such semiconductors capable of forming the hetero junction diode are available, for example, wide band cap semiconductors (such as GaN and diamond) and GaAs, then other semiconductors may be used.

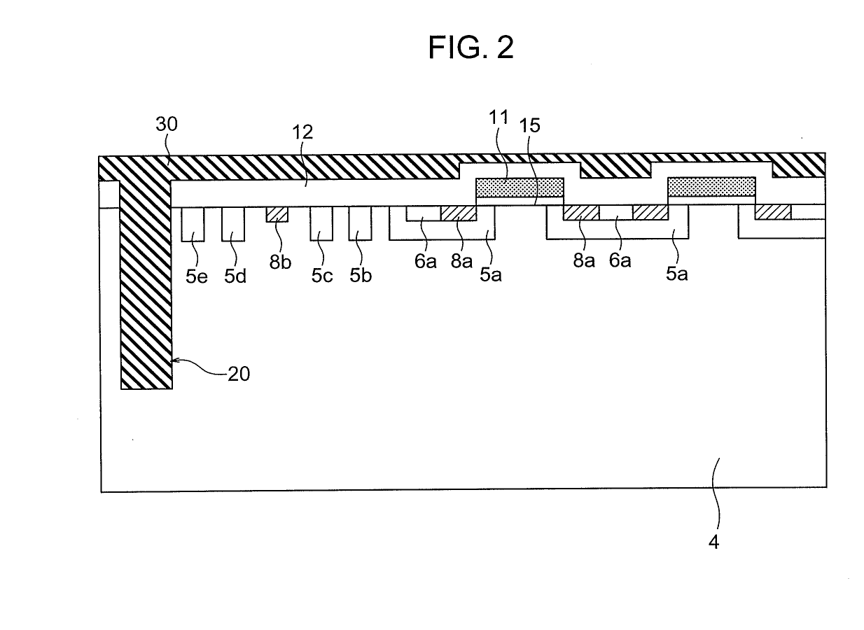

The polycrystal silicon semiconductor region 30a can be manufactured as follows: That is, for example, while a magnetically enhanced inductively coupled plasma etching is carried out under such a gas condition containing 90% SF₆ and 10% O₂ by employing either copper or nickel as a mask, a groove 20 is formed along a direction substantially perpendicular to the first major plane; as shown in FIG. 2, the polycrystal silicon layer 30 formed from the first major plane is deposited; and then, the deposited polycrystal silicon layer 30 is patterned. While the silicon semiconductor region 30a constitutes a floating field ring having such a dimension that a distance between the silicon semiconductor region 1 and the silicon semiconductor region 30a can be connected by a depletion layer, the depletion layer reaches the silicon semiconductor region 30a before a break-down phenomenon occurs due to concentration of electric fields in a peripheral area of the anode-sided semiconductor layer 1, so that the electric field concentration may be relaxed in the peripheral area of the anode-sided semiconductor layer 1. Furthermore, when a voltage is applied, the depletion layer is sequentially extended from the silicon semiconductor region 30a to the p type SiC semiconductor regions 5e and 5d which are arranged as the floating field ring, so that it can prevent a deterioration of the withstanding voltage which is caused by that the electric field is concentrated at a peripheral portion of the hetero junction diode. As a result, the high withstanding voltage can be achieved. Also, in the embodiment 1, the n type SiC semiconductor region 8b has been formed in order that a leak current does not flow through the surface of the first major plane. Alternatively, in such a case that impurity concentration of the n type SiC semiconductor region 4 is high, this n type SiC semiconductor region 8b is no longer provided. The embodiment 1 exemplifies such a case where the floating field rings 5e and 5d have also been provided on the first major plane. Alternatively, there are some possibilities that the necessary withstanding voltage may be obtained by merely forming the semiconductor layer 30a. It should also be understood that after the groove 20 has been formed, if necessary, an impurity may be alternatively implanted into an inside of the groove 20 by an oblique ion implantation in order that the leak current is suppressed, and also, the extension degree of the depletion layer is adjusted. Also, even when a thin oxide film such as a natural oxide film has been formed on a portion inside this groove 20, for example, a side wall thereof, if the potential of the silicon semiconductor region 30a in such a manner that the depletion layer is extended along the silicon semiconductor region 30a, then this thin oxide film of the groove 20 never causes a problem.

In the semiconductor device of this embodiment 1, the groove 20 is formed and then the polycrysal silicon is formed in this groove 20 in order to realize the silicon semiconductor region 30a. As a result, there is such a merit that a thermal step for a long time duration at a high temperature need not be employed, while this thermal step may give an adverse influence to a boundary plane of the gate insulating film 15 and an impurity profile of a major semiconductor region made of SiC.

Also, after the groove 20 has been formed, instead of the silicon semiconductor region 30a, since a p type impurity is implanted by an oblique ion implantation into the side plane of the groove 20, a p type SiC semiconductor region may be alternatively formed, and thereafter, this groove 20 may be alternatively embedded by an insulator. In this alternative case, there are some possibilities that a thermal process capable of activating the p type impurity formed on the side plane of the groove 20 cannot be sufficiently carried out. However, since the floating field rings 5e and 5d have been provided on the side of the first major face, the electric field concentration in the peripheral portion can be avoided due to a multiplier effect between the p type SiC semiconductor region and the floating field rings 5e and 5d, resulting in the high withstanding voltage.

It should also be noted that the high withstanding voltage forming means which is formed on the side of the first major plane is not such an extension region but also a diffusion region, which use a field plate and a low concentration p type semiconductor region in addition to the floating field rings as described in this embodiment 1, but may be alternatively realized by a floating Schotty diode which is manufactured by that a silicon semiconductor region is arranged in a ring shape similar to the floating field rings so as to be contacted to the wide band gap semiconductor region 4.

In the above-described semiconductor device, a dimension “X” of the n type SiC silicon semiconductor region 4 is made as thinner as possible by an etching treatment from the second major plane in order that the ON resistance of this semiconductor element is not increased, although such a thickness of this silicon semiconductor region 4 is secured in order that a necessary withstanding voltage can be secured. Thereafter, polycrystal silicon is deposited from the second major place so as to form a hetero junction between the deposited polycrystal silicon and the n type SiC semiconductor layer 4. Also, the thickness of the silicon semiconductor region 1 is made thick in such a manner that a thickness dimension “Y” of the semiconductor region becomes sufficiently thicker than the dimension “X” of the silicon semiconductor region 4 in order that the wafer can be hardly broken, and can be easily handled. Concretely speaking, it is desirable that the dimension “Y” is made at least 2 times, or more times larger than the dimension “X”, if possible, 3 times, or more times larger than this dimension “X.”

In this case, if such hetero junction diodes whose leak currents are small can be formed between the SiC semiconductor region 4 and the silicon semiconductor regions 1 and 30a, then these silicon semiconductor regions 1 and 30a may be made of polycrystal silicon layers and/or monocrystal silicon layers. Also, as to a type of an impurity, an n type impurity and/or a p type impurity may be freely selected, depending upon a value of a forward direction voltage and a magnitude of a leak current. However, since the resistance of the silicon semiconductor region 1 is added as a stray ON-resistance to the reverse blocking switching element, it is desirable that the impurity concentration is increased so as to lower the resistance value.

### Embodiment 2

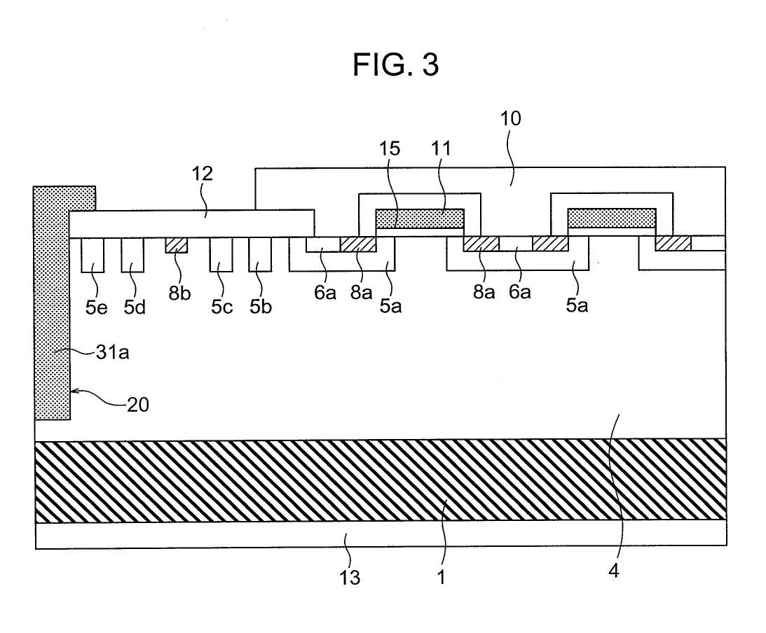

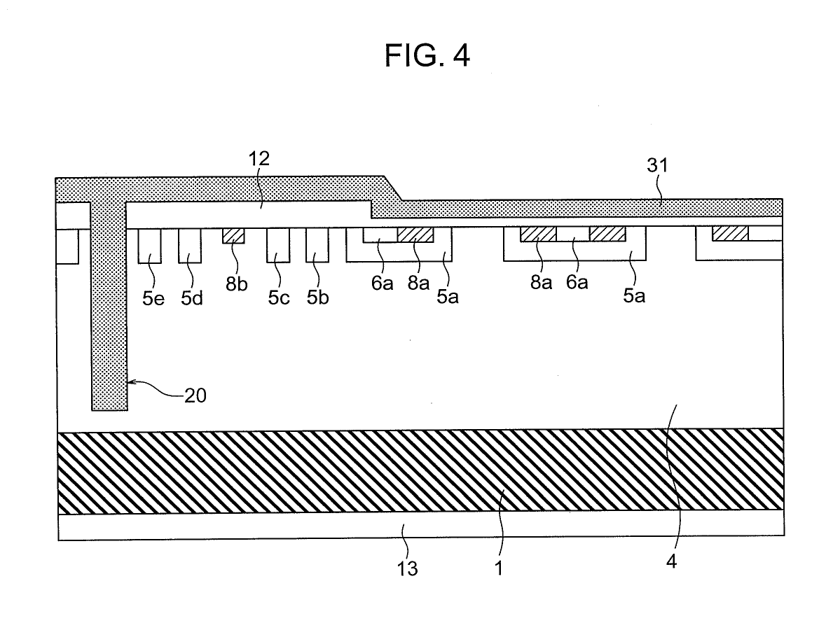

FIG. 3 indicates a semiconductor device according to an embodiment 2 of the present invention. This embodiment 2 corresponds to such a case that a silicon semiconductor region 31a formed based upon the same purpose as the silicon semiconductor region 30a of FIG. 1 is fabricated by using a polycrystal silicon layer 31 which is formed in the same step as a gate electrode layer 31 of a power MOSFET as shown in FIG. 4. It should be noted that although both the silicon semiconductor layer 31a and the gate electrode layer 11 may employ the polycrystal silicon semiconductor layer 31 formed in the same step, there is no problem even if types and concentration of the impurities are separately set. Alternatively, these layers may be formed as such polycrystal silicon layers into which the same type of impurity may be doped in high concentration.

### Embodiment 3

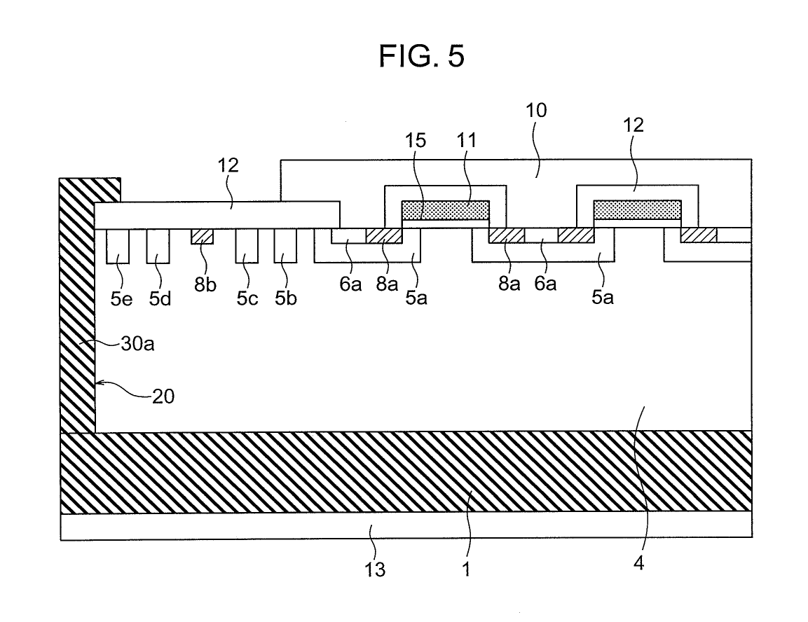

FIG. 5 indicates a semiconductor device according to an embodiment 3 of the present invention. This embodiment 3 corresponds to such a case that a silicon semiconductor region 30a is contacted to a silicon semiconductor region 1 in the semiconductor device of the embodiment 3. Even in such a case that an ohmic contact between the silicon semiconductor region 30a and the silicon semiconductor region 1 cannot be established, these two semiconductor regions 30a and 1 are connected to each other by a depletion layer which is extended from a hetero junction formed on the side of the second major plane, and is further extended from the side of the second major plane to the surface side, and when a high voltage is applied, the depletion layer is sequentially extended to the floating field rings 5e and 5d formed on the side of the major surface, so that electric field concentration in a preferable portion of the hetero junction can be avoided. As a consequence, similar to the embodiment 1, a high withstanding voltage of the hetero junction diode can be achieved.

### Embodiment 4

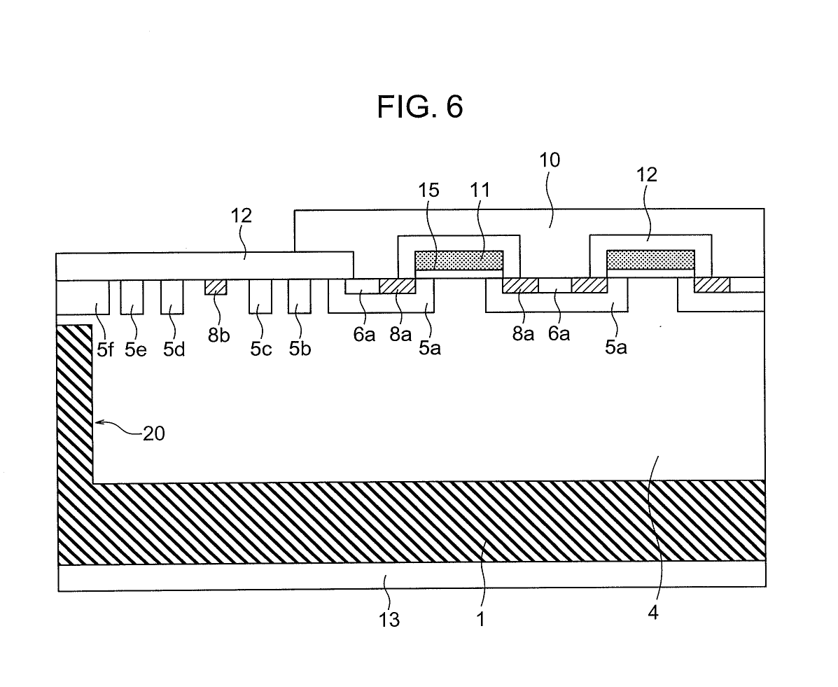

FIG. 6 indicates a semiconductor device according to an embodiment 4 of the present invention. This embodiment 4 corresponds to such a case that a groove 20 is formed from a rear surface of the semiconductor device, and the silicon semiconductor region 30a of FIG. 5 is realized by the same step for the silicon semiconductor region 1. The embodiment 4 shows such a case that although there is a gap between a p type diffusion region 5f formed in the first major plane and the silicon semiconductor region 1, since this gap is selected to be such a distance that a depletion layer is connected without any breakdown when a reverse voltage is applied to a hetero junction diode, the p type diffusion region 5f may be operated as the floating field ring, so that a high withstanding voltage of the hetero junction diode can be achieved. Also, even when this gap is not present, but the p type diffusion region 5f is contacted to the silicon semiconductor region 1, since the p type diffusion regions 5f and 5e are operated as the floating field rings, the high withstanding voltage of the hetero junction diode can be achieved due to the similar reason to that of the embodiment 2. In this embodiment 4, while the p type diffusion regions 5f and 5e are not formed, the groove 20 is made shallow, and even when a dimension along the vertical direction is short which corresponds to the silicon semiconductor region 30a of FIG. 5, an electric field at a peripheral portion of the hetero junction diode is relaxed. As a result, there is an effect with respect to the realization of the high withstanding voltage.

### Embodiment 5

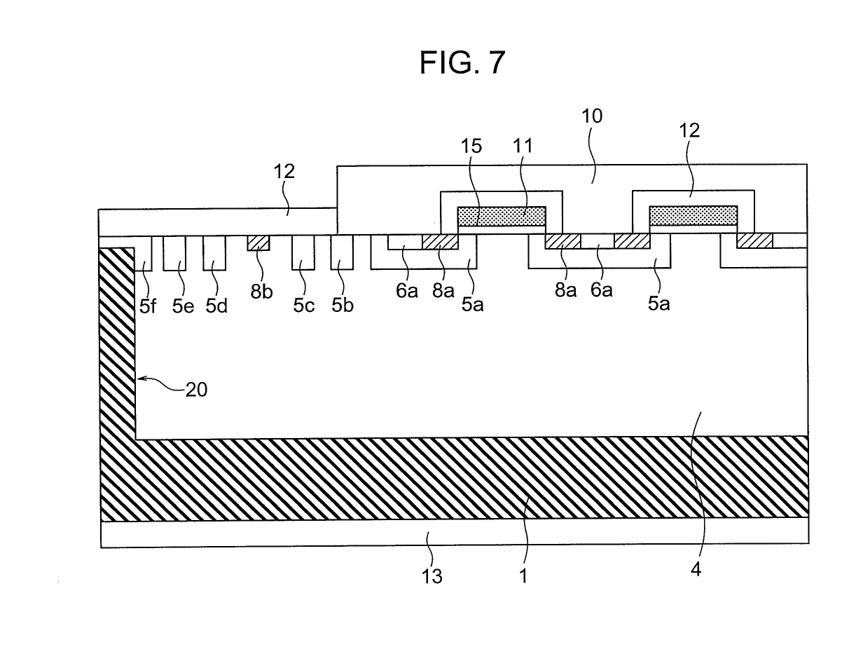

FIG. 7 indicates a semiconductor device according to an embodiment 5 of the present invention. This embodiment 5 corresponds to such a case that the silicon semiconductor region 1 is contacted to the p type diffusion region 5f in the embodiment 3. Also, in this embodiment 5, a depletion layer which is formed in the SiC semiconductor region 4 which is contacted to the silicon semiconductor region 1 is also connected to the p type diffusion region 5f, and this depletion layer is sequentially extended to the floating field rings 5e and 5d. As a result, an electric field at a terminal of a hetero junction diode may be relaxed, so that a high withstanding voltage of the hetero junction diode may be improved.

### Embodiment 6

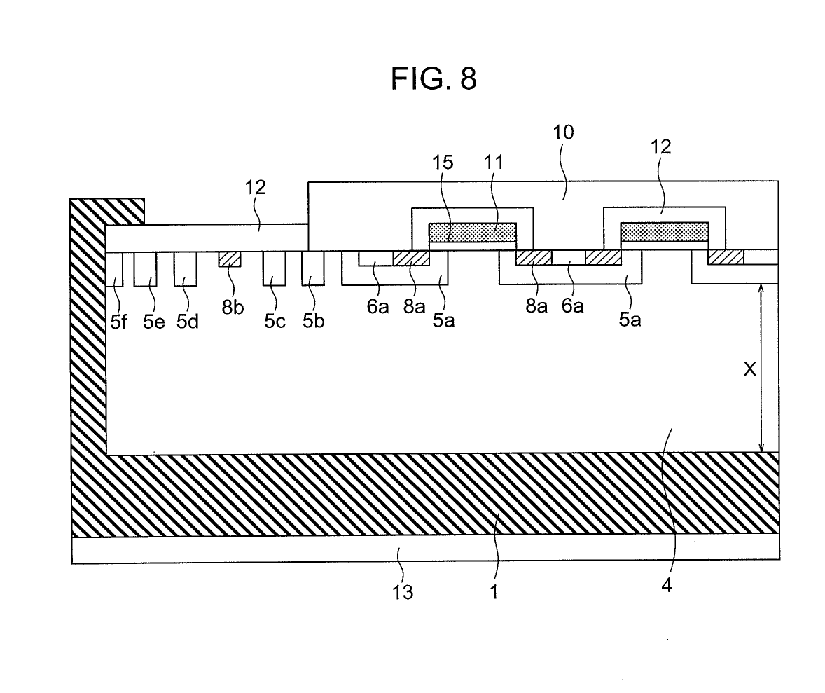

FIG. 8 indicates a semiconductor device according to an embodiment 6 of the present invention. This embodiment 6 corresponds to such a case that in a semiconductor element of this embodiment 6, after a semiconductor wafer has been dicing-processed, the dicing-processed semiconductor wafer is back-etched, and thereafter, a silicon semiconductor region 1 is formed.

In this case, since the silicon semiconductor region 1 is deposited on a side wall of the semiconductor chip, a shape similar to that of FIG. 5 may be obtained. It should be understood that in this embodiment 6, even when the chip dicing place is slightly shifted, in order that the withstanding voltage can be secured, the floating field ring 5f shown in FIG. 5 is formed in such a manner that this floating field ring 5f is extended up to the peripheral portion of the semiconductor chip, and is contacted to the silicon semiconductor region 1.

### Embodiment 7

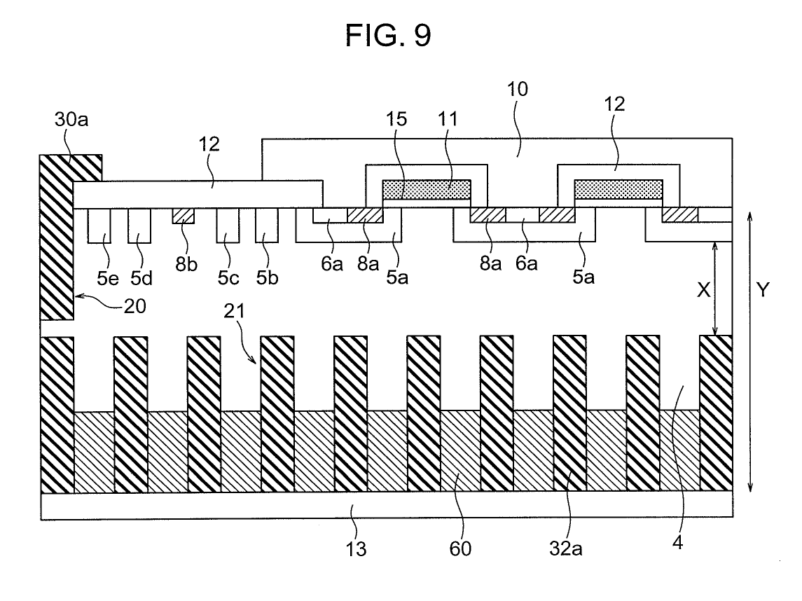

FIG. 9 shows a semiconductor device according to an embodiment 7 of the present invention. In a semiconductor element of this embodiment 7, while an SiC substrate containing a p type SiC region 60 is used, a silicon semiconductor region 30a is formed in a groove 20 on the side of a first major plane, and another silicon semiconductor region 32a is also formed in another groove 21 on the side of a second major plane. The magnetically enhanced inductively coupled plasma etching process is used also in the groove 21 on the side of the second major plane, so that the groove 21 can be formed in a high speed.

The semiconductor device of this embodiment 7 corresponds to such a case that an ON resistance is lowered, while a thickness dimension “Y” of the semiconductor device remains thick, another dimension “X” thereof is reduced to a minimum dimension which is required to secure a withstanding voltage, for example, when the withstanding voltage is lower than, or equal to 10 KV, the dimension “X” is reduced smaller than, or equal to several tens of μm. In this embodiment 7, a deep groove 21 has been formed from the second major plane; polycrystal silicon has been deposited in this groove 21; and then, a silicon semiconductor layer 32a has been formed. Although it is practically difficult to form a semiconductor region having a low resistance value in a wide band gap semiconductor, a silicon semiconductor layer 32a having a low resistance value is used in this embodiment 7, so that a resistance value of the second major plane on the side of the substrate can be lowered. Also, since the thickness “Y” of the semiconductor region can be made relatively thick, the wafer can be hardly broken and can be easily handled. A p type SiC region 60 is required in order that the semiconductor device of this embodiment 7 may have a reverse withstanding voltage.

In this embodiment 7, while the p type SiC region 60 is used as a substrate, it is possible to manufacture that the n type SiC semiconductor region 4 is formed on this p type SiC region 60 by using an epitaxial growth. Alternatively, while the n type SiC semiconductor region 4 is employed as the SiC substrate, the p type SiC semiconductor region 60 may be formed in low cost by a diffusion step from an ion implantation, or a diffusion source which contains a p type impurity in high concentrations. Otherwise, the p type SiC semiconductor region 60 may be alternatively formed as an insulating layer.

### Embodiment 8

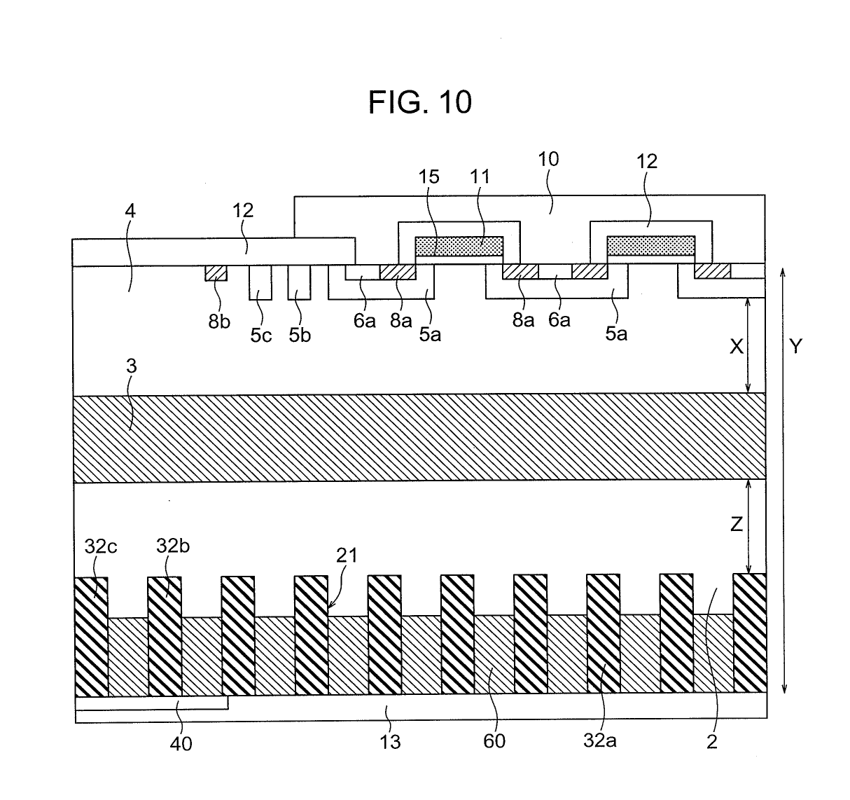

FIG. 10 shows a semiconductor device according to an embodiment 8 of the present invention. In a semiconductor element of this embodiment 8, an n type SiC semiconductor region 3 is provided between an n type SiC semiconductor region 4 and another n type semiconductor region 2, while a resistance value of the n type SiC semiconductor region 3 is sufficiently lower than the resistance values of these two n type SiC semiconductor regions 2 and 4, and is formed in high concentration. Concretely speaking, it is desirable that resistivity of the n type SiC semiconductor region 3 is lower than, or equal to resistivity of the n type SiC semiconductor regions 2 and 4 by 1 digit. However, even if the first-mentioned resistivity is lower than, or equal to ½ of the last-mentioned resistivity, there is an effect. Since this n type SiC semiconductor region 3 having the high concentration is formed, while an increase of the ON resistance is suppressed, the dimension of the semiconductor region “Y” can be made long at the same time. As a result, the wafer can be hardly broken, and can be easily handled.

In the semiconductor element of this embodiment 8, both a thickness “X” of the n type SiC semiconductor region 4 in order to secure the withstanding voltage of the power MOSFET, and a thickness “Z” of the n type SiC semiconductor region 4 required for the hetero junction diode formed on the side of the second major plane have been made as thin as possible, whereas a thickness “Y” of the semiconductor element has been made thick, which never causes a handling problem. In this embodiment 8, when the dimension “Y” becomes sufficiently longer than a sum of the dimension “X” and the dimension “Z”, there is a merit. For example, in such a case that when a semiconductor chip is accomplished, the dimensions “X” and “Y” become about 10 μm to about 20 μm, whereas the dimension “Y” becomes about 80 μm to about 600 μm, there is a merit.

Both a semiconductor layer 32b and another semiconductor layer 32c have been formed at the same time with a semiconductor layer 32a by the floating field ring on the side of the second major plane formed in such a manner that the floating ring surrounds a peripheral portion of the electrode 13. It should also be noted that the respective semiconductor layers 32a to 32c are electrically isolated from each other. Even when the withstanding voltage of the hetero junction diode of the second major plane is secured by the floating field ring formed in such a groove, there is no problem.

It should also be understood that even when the above-described n type SiC semiconductor region 3 having the high concentration is manufactured by employing other semiconductor materials than the semiconductor material whose resistivity is lower than, or equal to the resistivity of the semiconductor regions 2 and 4 by 1 digit, for example, a metal layer, there is no problem.

### Embodiment 9

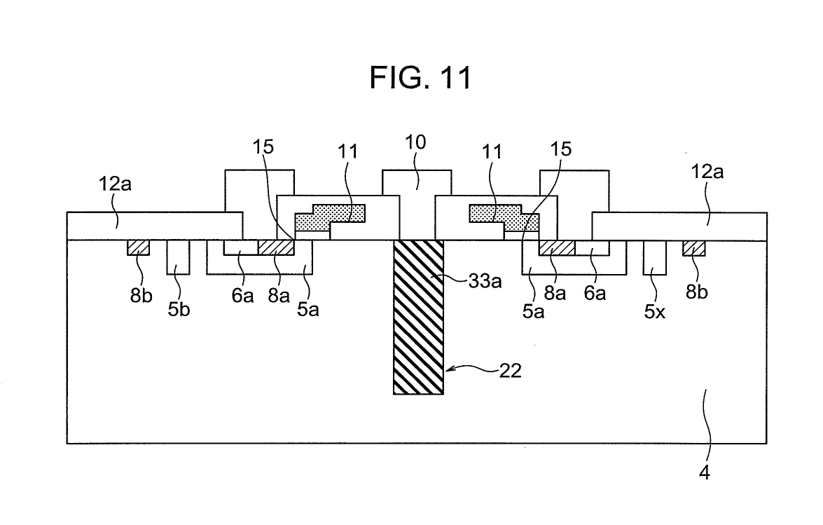

FIG. 11 indicates a semiconductor device according to an embodiment 9 of the present invention. This embodiment 9 corresponds to such a case that an anode electrode of a hetero junction diode is also derived from the side of the first major plane. In this embodiment 9, a groove 22 has been formed and a silicon semiconductor region 33a has been formed therein in such a manner that an area of a hetero junction diode is widened by which an ON resistance can be lowered. Similar to the embodiment 2, such a polycrystal silicon layer that the gate electrode layer 11 and the silicon semiconductor region 33a are formed in the same step may also be used in this embodiment 9. The above-explained semiconductor structure may also be used in an integrated circuit by adding an element isolation region known in the technical field.

### Embodiment 10

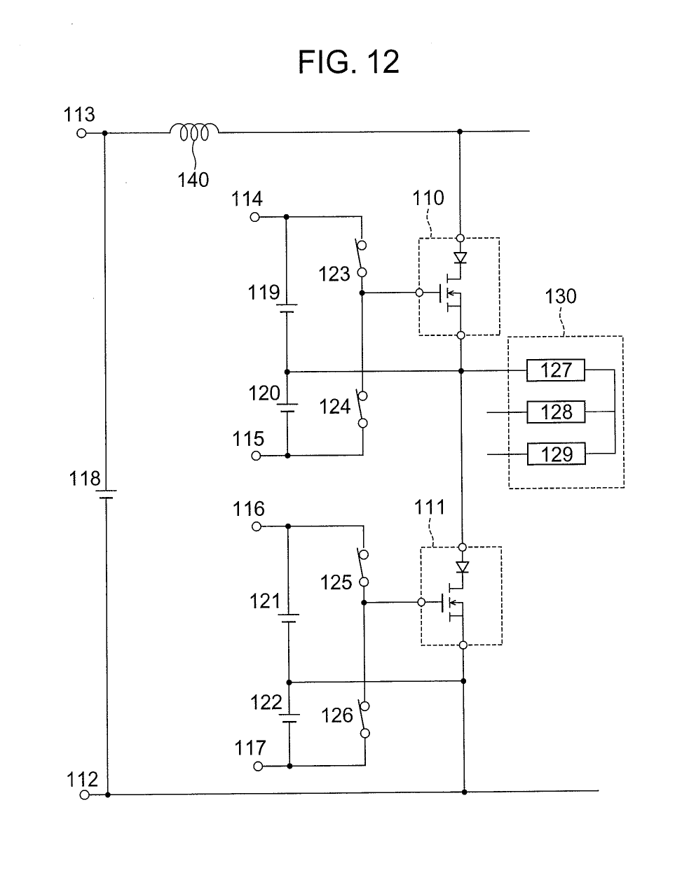

FIG. 12 represents a semiconductor circuit according to the present invention, which employs a semiconductor device of an above embodiment thereof. The circuit includes a ground terminal 112, a high voltage terminal 113, a high voltage power source 118, power sources 119-122, switches 123-126, terminals 114-117 and so on. This embodiment 10 corresponds to such an example that a reverse blocking switching element of the present invention with employment of a hetero junction diode is utilized in current-fed inverter(s) 110, 111. In the current-fed inverter, all of currents flowing through the inverter circuits become substantially constant due to a current smoothing reactor 140. The currents flow through reverse blocking switching elements which are different from each other in response to ON/OFF statuses of the respective switching elements. As a result, a current supplied to a load 130 such as a motor is controlled. In this embodiment 10, reference numerals 127, 128, 129 indicate coils of a 3-phase motor. When the semiconductor device of this embodiment 10 is used, since a switching element portion employs a wide band gap semiconductor, the switching element portion becomes low loss in a high voltage. Also, in a hetero junction diode portion, since impurity concentration and a type (either n type or p type) of an impurity as to a silicon semiconductor layer are optimized, such a diode can be realized which is operable in a high seed; a forward direction voltage of this diode is low; a leak current thereof is low; and minority carriers are not stored in this diode. As a consequence, there is such an effect that a current-fed power converting circuit such as a current-fed inverter can be driven in a high frequency, and further, loss thereof can be reduced.

### Embodiment 11

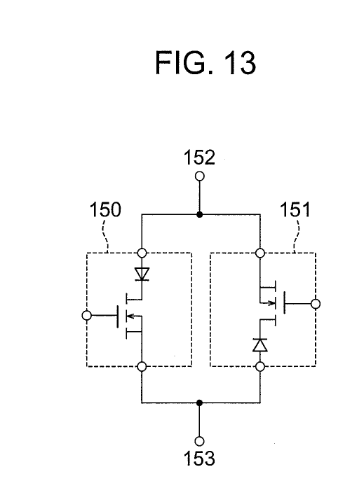

FIG. 13 represents a semiconductor circuit according to the present invention, which employs semiconductor device(s) 150, 151 of an above embodiment thereof. The reference number(s) 152, 153 indicates a terminal. The semiconductor device of this embodiment 11 corresponds to such a bi-directional switch with employment of reverse blocking switches which are utilized in a matrix converter circuit, while the matrix converter circuit is mainly employed in an elevator, and the like. As previously described, if the reverse blocking switches of the present invention are connected parallel to each other along a reverse direction, then the bi-directional switch can be realized. When such a bi-directional switch is employed in a matrix converter circuit, the matrix converter circuit operable in a high frequency and in low cost can be realized due to the same reason as explained in the embodiment 10.

In the above-descriptions, the type of power semiconductor element has been explained as the n type. As apparent from the foregoing description, in the case of a p type power semiconductor element, since a polarity of a circuit thereof and a polarity of an impurity layer thereof are reversed, a similar semiconductor structure may be realized and a similar effect may be obtained.

Also, the above explanations have been made of such a case that SiC is employed in the semiconductor region which constitutes the switching element. Alternatively, even when other wide band gap semiconductors such as GaN and diamond, and GaAs are employed, there is no problem. Also, in the above description, silicon has been used as the semiconductor whose band gap is small and which constitutes the hetero junction. Alternatively, if other semiconductors are capable of constructing such a hetero junction, then these semiconductors have no problem.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor switching element comprising: a first junction and a second junction; wherein:
at least one region within major current paths between a first main terminal and a second main terminal of said semiconductor switching element corresponds to a wide band gap semiconductor;
a voltage drop of said second junction in a forward direction is lower than a voltage drop of said first junction in a forward direction;
when said semiconductor switching element is turned ON in the forward direction operation, said second junction is brought into a forward bias status; when said semiconductor switching element is in a reverse bias status, said semiconductor switching element is brought into a current blocking status; and a unit is provided, in which a depletion layer of a peripheral edge portion of said second junction is extended to the side of a first major plane where said first junction is formed when said semiconductor switching element is under said current blocking status.

2. The semiconductor switching element as claimed in claim 1 wherein:
said second junction is a hetero junction, and one of the semiconductors which constitute said hetero junction is a silicon semiconductor; and
at least one semiconductor of said first junction is a wide band gap semiconductor.

3. The semiconductor switching element as claimed in claim 1 wherein:
as said unit in which the depletion layer at the peripheral edge portion of said second junction is extended to the side of said first major plane where the first junction is formed, a silicon semiconductor region is formed in the vicinity of the peripheral edge portion of said second junction and further on the side of the first major plane.

4. A semiconductor switching element comprising: a switching element on the side of a first terminal and having a hetero junction diode on the side of a second terminal, which blocks a reverse direction current,
wherein:
said hetero junction diode is constituted by a first semiconductor region made of a first semiconductor whose band gap is wider, and a second semiconductor region made of a second semiconductor whose band gap is narrower; and
said semiconductor switching element is comprised of a unit for extending a depletion layer at a peripheral portion of said second semiconductor region made of the second semiconductor along a side plane of said first semiconductor region made of said first semiconductor.

5. A semiconductor switching element comprising: a switching element on the side of a first terminal and having a hetero junction diode on the side of a second terminal, which blocks a reverse direction current,
wherein:
said hetero junction diode is constituted by a first semiconductor region made of a first semiconductor whose band gap is wider, and a second semiconductor region made of a second semiconductor whose band gap is narrower; and
said semiconductor switching element is comprised of a unit for extending a depletion layer at a peripheral portion of said second semiconductor region made of the second semiconductor along a direction perpendicular to a first major plane.

6. The semiconductor switching element as claimed in claim 5 wherein:
said first terminal is formed on the first major plane side of the semiconductor;
said second terminal is formed on the second major plane side of the semiconductor; and
as said unit for extending the depletion layer at a peripheral portion of a second region of said second semiconductor along the vertical direction with respect to said first major plane, a third semiconductor region made of the second semiconductor is provided between said first major plane and said second major plane at the peripheral portion of the second region of the second semiconductor.

7. The semiconductor switching element as claimed in claim 6 wherein:
said third semiconductor region made of the second semiconductor is formed in a groove which is formed in said first semiconductor region of said first semiconductor along a direction substantially perpendicular to said first major plane.

8. The semiconductor switching element as claimed in claim 5 wherein:
said unit for extending the depletion layer extended to the first major plane side from a peripheral portion of a semiconductor chip to an inside direction is provided by the unit for extending the depletion layer at the peripheral portion of said second semiconductor region made of said second semiconductor along the vertical direction with respect to said first major plane.

9. The semiconductor switching element as claimed in claim 5 wherein:
as the unit for extending the depletion layer at the peripheral portion of said second semiconductor region made of said second semiconductor along the vertical direction with respect to said first major plane, a fifth semiconductor region made of a first semiconductor having a conductivity type opposite to that of the first semiconductor region made of the first semiconductor is provided on a side plane of the first semiconductor region made of the first semiconductor; and
a high withstanding voltage securing region such as a floating field ring, a field plate, and a low concentration extension region is provided on the first major plane, while said high withstanding voltage security region is employed in order to relax concentration of electric fields of the depletion layer extended from the second major plane.

10. The semiconductor switching element as claimed in claim 8 wherein:
as the unit for extending the depletion layer from the peripheral portion of said semiconductor chip to the inner side direction, a high withstanding voltage securing region such as a floating field ring, a field plate, and a low concentration extension region is provided on the first major plane.

11. The semiconductor switching element as claimed in claim 5 wherein:
said second semiconductor region made of said second semiconductor is formed in a groove formed in said second major plane; and
a fourth semiconductor region made of the first semiconductor having a polarity opposite to the polarity of said first semiconductor region made of the first semiconductor is formed on the second major plane side where said second semiconductor region made of the second semiconductor is not formed.

12. A semiconductor switching element comprising: a switching element on the side of a first terminal and having a hetero junction diode on the side of a second terminal, which blocks a reverse direction current,
wherein:
said hetero junction diode is constituted by a first semiconductor region made of a first semiconductor whose band gap is wider, and a second semiconductor region made of a second semiconductor whose band gap is narrower; and
said second semiconductor region made of the second semiconductor is provided along a vertical direction with respect to a first major plane.

13. The semiconductor switching element as claimed in claim 12 wherein:
said second semiconductor region made of the second semiconductor is formed in a groove which is formed in said first semiconductor region of said first semiconductor along a direction substantially perpendicular to said first major plane.

14. A semiconductor switching element having a switching element on the side of a first terminal and having a hetero junction diode on the side of a second terminal, which blocks a reverse direction current, wherein:
said first terminal is provided on a first major plane, and said second terminal is provided on a second major plane;
said hetero junction diode is constituted by a first semiconductor region made of a first semiconductor whose band gap is wider, and a second semiconductor region made of a second semiconductor whose band gap is narrower; and
said hetero junction diode is located adjacent to said first semiconductor region made of the first semiconductor, and is contacted to a switching element on the side of said first terminal via a low resistance region whose resistivity is lower than, or equal to resistivity of said first semiconductor region made of the first semiconductor by 1 digit.

15. A current-fed power converting apparatus comprising:
the semiconductor switching element recited in claim 1.

16. A bi-directional switch circuit comprising:
the semiconductor switching element recited in claim 1.
